(19) United States
(12) Patent Application Publication
(10) Pub. No.: US 2006/0193174 A1
(43) Pub. Date: Aug. 31, 2006

(54) Non-volatile and static random access memory cells sharing the same bitlines

(75) Inventors: David S. Choi, Cupertino, CA (US); Eui Pil Kwon, San Jose, CA (US); Kyu Hyun Choi, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: O2IC, Santa Clara, CA (US)

(21) Appl. No.: 11/067,313

(22) Filed: Feb. 25, 2005

(51) Int. Cl. G11C 11/34; G11C 14/00

(52) U.S. Cl. 365/185.08

(57) ABSTRACT

A memory cell structure includes non-volatile as well as SRAM memory cells that share the same bitline and operate differentially. The SRAM cell includes first and second MOS transistors that are coupled to the same true and complementary bit lines that the non-volatile memory cells are coupled to. The non-volatile memory cells are erased prior to being programmed. Programming of the non-volatile memory cells may be carried out via hot-electron injection or Fowler-Nordheim tunneling. Data stored in the non-volatile memory cells may be transferred to the SRAM cell. The differential reading and writing of data reduces over-erase of the non-volatile devices.

### CROSS-REFERENCES TO RELATED APPLICATIONS

The present application is related to copending application Ser. No. 10/394,417, entitled “Non-Volatile Memory Device,” filed Mar. 19, 2003, Attorney Docket No. 021801-000210US, assigned to the same assignee, and incorporated herein by reference in their entirety.

### BACKGROUND OF THE INVENTION

The present invention relates to semiconductor integrated circuits. More particularly, the invention provides a semiconductor memory structure that has integrated non-volatile and static random access memory cells. Although the invention has been applied to a single integrated memory structure in a memory application, there can be other alternatives, variations, and modifications. For example, the invention can be applied to embedded memory applications, including those with logic or micro circuits, and the like.

Semiconductor memory devices have been widely used in electronic systems to store data. There are generally two types of memories, including non-volatile and volatile memories. The volatile memory, such as a Static Random Access Memory (SRAM) or a Dynamic Random Access Memory (DRAM), loses its stored data if the power applied has been turned off. SRAMs and DRAMs often include a multitude of memory cells disposed in a two dimensional array. Due to its larger memory cell size, an SRAM is typically more expensive to manufacture than a DRAM. An SRAM typically, however, has a smaller read access time and a lower power consumption than a DRAM. Therefore, where fast access to data or low power is needed, SRAMs are often used to store the data.

Non-volatile semiconductor memory devices are also well known. A non-volatile semiconductor memory device, such as a flash Erasable Programmable Read Only Memory (Flash EPROM), Electrically Erasable Programmable Read Only Memory (EEPROM) or, Metal Nitride Oxide Semiconductor (MNOS), retains its charge even after the power applied thereto is turned off. Therefore, where loss of data due to power failure or termination is unacceptable, a non-volatile memory is used to store the data.

Unfortunately, a non-volatile semiconductor memory is typically slower to operate than a volatile memory. Therefore, where fast store and retrieval of data is required, the non-volatile memory is not typically used. Furthermore, the non-volatile memory often requires a high voltage, e.g., 12 volts, to program or erase. Such high voltages may cause a number of disadvantages. The high voltage increases the power consumption and thus shortens the lifetime of the battery powering the memory. The high voltage may degrade the ability of the memory to retain its charges due to hot-electron injection. The high voltage may cause the memory cells to be over-erased during erase cycles. Cell over-erase results in faulty readout of data stored in the memory cells.

The growth in demand for battery-operated portable electronic devices, such as cellular phones or personal organizers, has brought to the fore the need to dispose both volatile as well as non-volatile memories within the same portable device. When disposed in the same electronic device, the volatile memory is typically loaded with data during a configuration cycle. The volatile memory thus provides fast access to the stored data. Unfortunately, most of the portable electronic devices may still require at least two devices, including the non-volatile and volatile, to carry out backup operations. Two devices are often required since each of the devices often rely on different process technologies, which are often incompatible with each other.

One disadvantage of using two separate devices, including non-volatile and volatile devices, is the data transfer from one device to another. If there is a lot of data that needs to be transferred from one device to another, and if the data bus width between the two devices is small compared to the amount of data to be transferred, then the data transfer may suffer from long transfer times. In addition, long transfer times may also result in a large power consumption, which is undesirable when battery life is limited. As merely an example, if the non-volatile memory device and the volatile memory device each has a capacity 64 Megabits, and if they share a 16 bit bus, i.e., the bus can only transfer 16 bits during one cycle period, then the transfer of all 64 Megabits of data from one device to the other would requires 4,194,304 cycle periods. The cumulative data transfer time may thus be undesirably long and the total power consumed may be undesirably too large. In addition, if a CPU is required to transfer data between the non-volatile and volatile devices, then the total amount of time spent transferring data will have an adverse impact on the CPU's ability to perform other tasks.

To increase the battery life, and reduce the cost associated with disposing both non-volatile and volatile memory devices in the same electronic device, and further to improve transfer speed performance, non-volatile SRAMs and non-volatile DRAMs have been developed. Such devices have the non-volatile characteristics of non-volatile memories, i.e., retain their charge during a power-off cycle, but provide the relatively fast access times of the volatile memories.

As merely an example, FIG. 1 is a transistor schematic diagram of a prior art non-volatile SRAM 40. Non-volatile SRAM 40 includes transistors 42, 44, 46, 48, 50, 52, 54, 56, resistors 58, 60 and Flash EEPROM memory cells 62, 64. Transistors 48, 50, 52, 54 and resistors 58, 60 form a static RAM cell. Transistors 42, 44, 46, 56 are select transistors coupling EEPROM memory cells 62 and 64 to the supply voltage Vcc and the static RAM cell. Transistors 48 and 54 couple the SRAM memory cell to the true and complement bitlines BL and \overline{BL}.

SRAM 40 consumes relatively large amount of power and occupies a relative large semiconductor surface area. Accordingly, a need continues to exist for a relatively small non-volatile SRAM that consumes less power than those in the prior art.

While the invention is described in conjunction with the preferred embodiments, this description is not intended in any way as a limitation to the scope of the invention. Modifications, changes, and variations, which are apparent to those skilled in the art can be made in the arrangement, operation and details of construction of the invention disclosed herein without departing from the spirit and scope of the invention.

### BRIEF SUMMARY OF THE INVENTION

According to the present invention, an improved memory structure and method is provided. More particularly, the invention provides a semiconductor memory structure that has integrated non-volatile and static random access memory cells sharing the same bitlines. Although the invention has been applied to a single integrated memory structure in a memory application, there can be other alternatives, variations, and modifications. For example, the invention can be applied to embedded memory applications, including those with logic or micro circuits, and the like.

In accordance with the present invention, an integrated memory structure includes at least one pair of non-volatile memory cells and at least one static random access memory (SRAM) cell. The SRAM cell includes first, second, third and fourth MOS transistors that are coupled to a pair of true and complementary bitlines associated with the integrated memory structure, and to first and second nodes of the integrated memory structure each having an associated capacitance. The SRAM cell also includes a pair of resistive loads which are coupled to the first and second nodes respectively. The non-volatile memory cells are coupled to the same true and complement bitline.

The first MOS transistor of the SRAM cell has a source terminal coupled to the first node, a drain terminal coupled to the true bitline associated with the integrated memory structure (hereinafter alternatively referred to as memory structure), and a gate terminal coupled to a first terminal of the memory structure. The second MOS transistor of the SRAM cell has a drain terminal coupled to the first node, a gate terminal coupled to a second node of the memory structure, and a source terminal coupled to the ground. The third MOS transistor of the SRAM cell has a source terminal coupled to the second node, a drain terminal coupled to the complement bitline associated with the memory structure, and a gate terminal coupled to the first terminal of the memory structure. The fourth MOS transistor of the SRAM cell has a drain terminal coupled to the second node, a gate terminal coupled to the first node, and a source terminal coupled to the ground. The first resistive load of the SRAM cell is coupled to the first node and also to a second terminal of the memory structure. The second resistive load of the SRAM cell is coupled to the second node and also to the second terminal of the memory structure. Each resistive load may be a resistor, an NMOS transistor, a PMOS transistor, etc.

The first non-volatile memory cell includes a substrate region coupled to a third terminal of the memory structure, a source region formed in the substrate region and coupled to the true bitline associated with the memory structure, a drain region formed in the substrate region and separated from the source region by a first channel region, a first gate overlaying a first portion of the channel region and separated therefrom via a first insulating layer, and a second gate overlaying a second portion of the channel region and separated therefrom via a second insulating layer. The first portion and second portions of the channel region do not overlap. The drain region of the first non-volatile memory cell is coupled to the fourth terminal of the memory structure. The first gate of the first non-volatile memory cell is coupled to the fifth terminal of the memory structure. The second gate of the first non-volatile memory cell is coupled to the sixth terminal of the memory structure.

The second non-volatile memory cell includes a substrate region coupled to the third terminal of the memory structure, a source region formed in the substrate region and coupled to the complementary bitline associated with the memory structure, a drain region formed in the substrate region and separated from the source region by a first channel region, a first gate overlaying a first portion of the channel region and separated therefrom via a first insulating layer, and a second gate overlaying a second portion of the channel region and separated therefrom via a second insulating layer. The first portion and second portions of the channel region do not overlap. The drain region of the second non-volatile memory cell is coupled to the fourth terminal of the memory structure. The first gate of the second non-volatile memory cell is coupled to the fifth terminal of the memory structure. The second gate of the second non-volatile memory cell is coupled to the sixth terminal of the memory structure.

The SRAM cell may be programmed during a write cycle. During such a cycle, one of the true and complementary bitlines associated with the memory structure is raised to, e.g., Vcc volts. The other bitline is set to a voltage complementary to the voltage of the first bitline (i.e., 0 volts). The first terminal of the memory structure is also raised to the Vcc supply voltage. This causes the SRAM cell to store either a 1 or a 0 in its associated capacitor.

The non-volatile memory cells may be programmed during a write cycle. Prior to storing the data in the non-volatile memory cells, the non-volatile memory cells are erased by applying a relatively high negative voltage to the fourth terminal of the memory cell, while applying, e.g., 0 volt to the remaining terminals of the memory structure. During such a write cycle, one of the bitlines associated with the memory structure is raised to, e.g., Vcc volts. The other bitline is set to a voltage complementary to the voltage of the first bitline (i.e., 0 volts). The bitlines are driven by an external voltage.

Data may also be transferred from the SRAM cell to the non-volatile memory cell after the SRAM cell has been programmed. The non-volatile memory cells are first erased as described above. Then, during the data transfer, the first terminal is raised to Vcc volts, thereby coupling the SRAM cell to the bitlines. No external voltage is applied to the bitlines. Thus one of the bitlines is raised to, e.g., Vcc volts, and the other bitline is set to a voltage complementary to the voltage of the first bitline (i.e., 0 volts), according to the voltages stored in the first and second nodes of the SRAM cell.

Programming of the non-volatile memory cells may be carried out via either hot-electron injection or Fowler-Nordheim tunneling. When subjected to either hot-electron injection or Fowler-Nordheim tunneling, more electrons are injected and trapped in the non-volatile memory cell coupled to the SRAM node storing a 0 than are trapped in the non-volatile device coupled to the SRAM node storing a 1. The threshold voltage of the non-volatile memory cell having more trapped electrons thus increases more than the threshold voltage of the other non-volatile memory cell. This completes the programming cycle.

To read the data stored in the non-volatile memory cells, the Vcc supply voltage is applied to the fourth and sixth terminals of the memory structure. A read sensing voltage is applied to the fifth terminal of the memory structure. The read sensing voltage is smaller than the Vcc supply voltage and is so selected as to disable current flow or, in the alternative, cause relatively small current to flow in the non-volatile memory cell that has more trapped electrons. Therefore, the non-volatile memory cell with no or fewer trapped electrons conducts a relatively larger current than the non-volatile memory cell that has more trapped electrons. This differential current flow causes the true and complementary bitlines to be charged or discharged to their previous states.

Data may also be transferred to the SRAM cell from the non-volatile memory cell after the non-volatile memory cells have been programmed. To load (store) the data stored in the non-volatile memory cells in the SRAM cell, the sixth, fourth and fifth terminals of the memory structure are raised to a first high voltage and the first terminal of the memory structure is supplied with a supply voltage Vcc that is lower than the first high voltage.

A multitude of the memory structures of the present invention may be used to form an array. The multitude of memory structures may be connected to the same wordline by connecting their first input terminals to that wordline. Accordingly, the multitude of memory structures may perform the loading of data to their associated SRAM cells from their associated non-volatile memory cells via their respective bitlines concurrently. As a result, the total data transfer time from the non-volatile memory cells to their associated SRAM cells when the SRAM cells are loaded concurrently is shorter than when the SRAM cells are loaded individually. In addition, as a consequence of the faster total transfer time, the concurrent loading of the SRAM cells may be more power efficient than if the SRAM cells were to be loaded individually.

In accordance with the present invention, since the non-volatile and the SRAM memory cells of each memory structure share the same pair of bitlines, data may be loaded from the SRAM cells to their associated non-volatile memory cells via their respective pair of bitlines concurrently. The total transfer time from the SRAM cells to the nonvolatile memory cells when the nonvolatile memory cells are loaded concurrently is shorter than when the nonvolatile memory cells are loaded individually. In addition, as a consequence of the faster total data transfer time, the concurrent loading of non-volatile memory cells may be more power efficient than if the non-volatile memory cells were to be loaded individually.

The accompanying drawings, which are incorporated in and form part of the specification, illustrate embodiments of the invention and, together with the description, serve to explain the principles of the invention.

### BRIEF DESCRIPTION OF THE DRAWINGS

FIG. 1 is a simplified transistor schematic diagram of a non-volatile SRAM, as known in the prior art.

FIG. 2 is a simplified transistor schematic diagram of a differential integrated memory cell structure, in accordance with one embodiment of the present invention.

FIG. 3 is a cross-sectional view of a first embodiment of a non-volatile memory cell disposed in the integrated memory cell structure of FIG. 2, in accordance with the present invention.

FIG. 4 is a cross-sectional view of a second embodiment of a non-volatile memory cell disposed in integrated memory cell structure of FIG. 2, in accordance with the present invention.

FIG. 5 is a simplified timing diagram associated with a write cycle of the volatile memory cell of the integrated memory cell structure of FIG. 2.

FIG. 6 is a simplified timing diagram associated with a read cycle of the volatile memory cell of the integrated memory cell structure of FIG. 2.

FIG. 7 is a simplified timing diagram of the volatile memory cell of the integrated memory cell structure of FIG. 2 during a recall cycle.

FIG. 8 is a simplified transistor schematic diagram of an integrated memory cell structure, in accordance with a second embodiment of the present invention.

FIG. 9 is a simplified schematic diagram of an integrated memory cell structure, in accordance with a third embodiment of the present invention.

FIG. 10 is a simplified floor plan diagram of an array of integrated memory cell structures, where the non-volatile memory cells and SRAM cell associated with each integrated memory structure are disposed adjacent each other.

FIG. 11 is a simplified floor plan diagram of an array of integrated memory cell structures, where the non-volatile memory cells and SRAM cell associated with each integrated memory structure are not disposed adjacent each other.

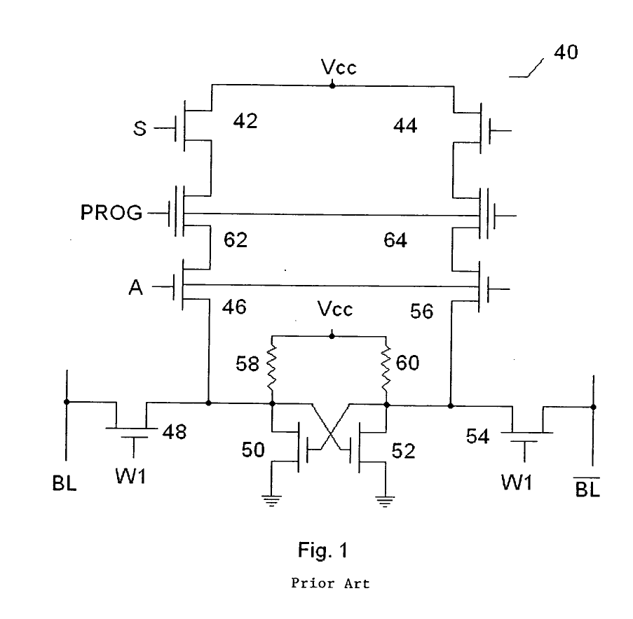

### DETAILED DESCRIPTION OF THE INVENTION

According to the present invention, an improved memory structure and method is provided. More particularly, the invention provides a semiconductor memory that has integrated non-volatile and static random access memory cells structures sharing the same bitlines. Although the invention has been applied to a single integrated memory structure in a memory application, there can be other alternatives, variations, and modifications. For example, the invention can be applied to embedded memory applications, including those with logic or microcircuits, and the like.

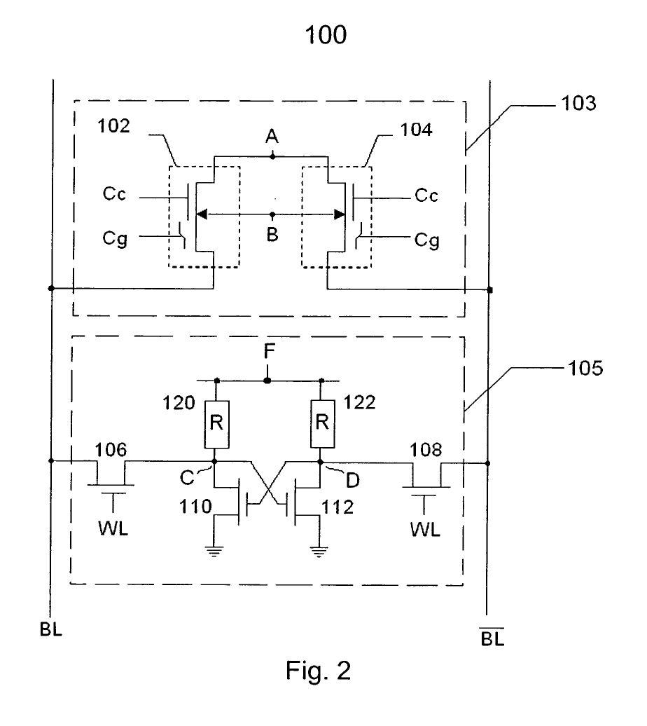

FIG. 2 is a transistor schematic diagram of an integrated memory structure 100 that operates differentially and includes both non-volatile memory cells and an SRAM cell, in accordance with one embodiment of the present invention. This diagram is merely an example, which should not unduly limit the scope of the claims herein. One of ordinary skill in the art would recognize many other variations, modifications, and alternatives. Integrated memory structure (hereinafter alternatively referred to as memory structure) 100 includes non-volatile memory cells 102, 104, N-channel Metal-Oxide-Semiconductor (MOS) transistors 106, 110 which together form a first latch cell, NMOS transistors 108, 112 which together form a second latch cell, and resistive loads 120,122, that together with NMOS transistors 106, 108, 110, and 112 form an SRAM cell 105.

In some embodiments, the integrated memory structure is similar to that shown in FIG. 2, except that it does not include resistive loads 120, 122. In such embodiments, to maintain the data stored in first and second latches, refresh operations are periodically performed. In the following, the SRAM cells and the latches may be alternatively and collectively referred to as SRAM or SRAM cell.

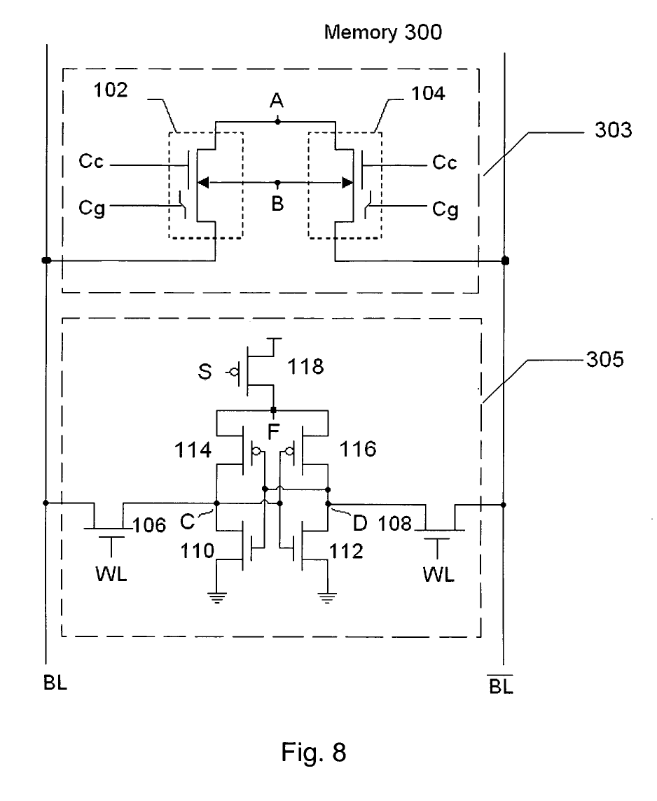

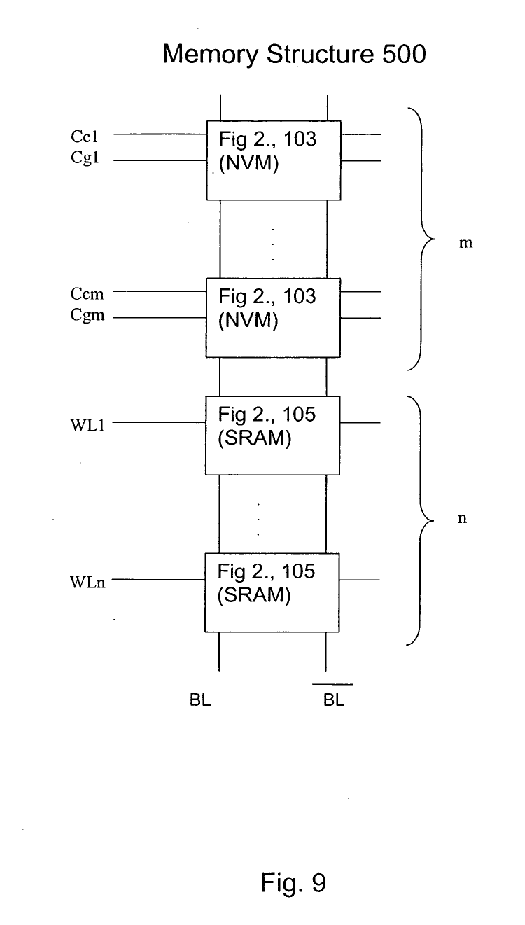

FIG. 8 shows a schematic diagram of a non-volatile SRAM 300, in accordance with another embodiment of the present invention. Non-volatile SRAM 300 is similar to non-volatile SRAM 100 except that in place of resistive loads 120, 122, it includes PMOS transistors 114, 116, and 118. PMOS transistor 114 has a source terminal coupled to the drain terminal of PMOS transistor 118, a drain terminal coupled to the source terminal of NMOS transistor 110, and a gate terminal coupled to the gate terminal of NMOS transistor 110. PMOS transistor 116 has a source terminal coupled to the drain terminal of PMOS transistor 118, a drain terminal coupled to the source terminal of NMOS transistor 112, and a gate terminal coupled to the gate terminal of NMOS transistor 112. The source terminals of PMOS transistors 114 and 116 are supplied with the supply voltage Vcc via transistor 118. The gate terminal of PMOS transistor 118 is coupled to a control circuit (not shown) to enable or disable the application of the voltage Vcc to terminal F. PMOS transistor 118 is maintained in an on-state except during the time when data transfer from non-volatile memory cell 303 to SRAM cell 305 is performed. In the embodiment 300, MOS transistors 114, 116 and 118 are shown as being PMOS transistors. It is understood, however, that MOS transistors 114, 116 and 118 may be NMOS transistors. PMOS transistor 114,116 may provide better stability for SRAM than the resistive loads 102, 122 (FIG. 2) as is well known. The following description is provided with reference to embodiment 100 of integrated memory structure shown in FIG. 2. It is understood, however, that the same description applies to embodiment 300 of integrated memory structure shown in FIG. 8.

Each of integrated memory structures 100, 300 includes terminals Cg, Cc, WL, BL and \overline{BL}. Each of memory structures 100, 300 may be part of a memory array (not shown) disposed in a semiconductor Integrated Circuit (IC) adapted, among other functions, to store and supply the stored data. Terminals BL and \overline{BL} typically form true and complementary bitlines of such a memory array and terminal WL typically forms a wordline of such a memory array. In the following terminals BL and \overline{BL} are alternatively referred to as bitlines BL and \overline{BL}, respectively. In the following terminal WL is alternatively referred to as wordline WL.

Referring to FIG. 2, the gate terminals of both MOS transistors 106 and 108 are coupled to wordline WL. The drain terminals of MOS transistor 106, 108 are respectively coupled to bit lines BL and \overline{BL}. The source terminals of MOS transistor 106, 108 are respectively coupled to nodes C and D. Node C is also coupled to the gate terminal of MOS transistor 112 and to the drain terminal of MOS transistor 110 and to one of the terminals of resistive load 120. Similarly, node D is coupled to the gate terminal of MOS transistor 110 and to the drain terminal of MOS transistor 112 and to one of the terminals of resistive load 122. The source terminals of MOS transistors 110, 112 are coupled to the Vₛₛ terminal. The other terminals of resistive load 120,122 are coupled to terminal F. Non-volatile memory devices 102, 104 each have a guiding gate and a control gate. The guiding gate terminals of non-volatile memory cells 102, 104 are coupled to input terminal Cg of memory structure 100. The control gate terminals of non-volatile memory cells 102, 104 are coupled to input terminal Cc of memory structure 100. The drain terminals of non-volatile memory cells 102, 104 are coupled to input terminal A of memory structure 100. The source terminals of non-volatile memory cells 102, 104 are respectively coupled to bit lines BL and \overline{BL}. The body (i.e., the bulk) terminals of non-volatile memory cells 102, 104 are coupled to input terminal B of memory structure 100. Non-volatile memory cells 102, and 104 are alternatively and collectively referred to herein below as memory cells 103, as shown in FIG. 2.

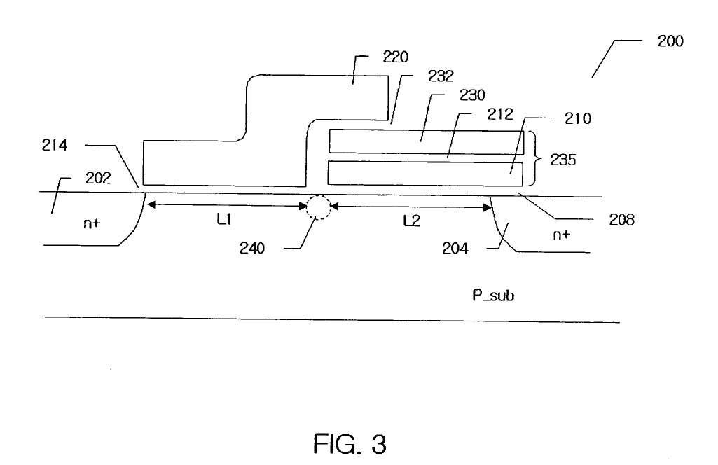

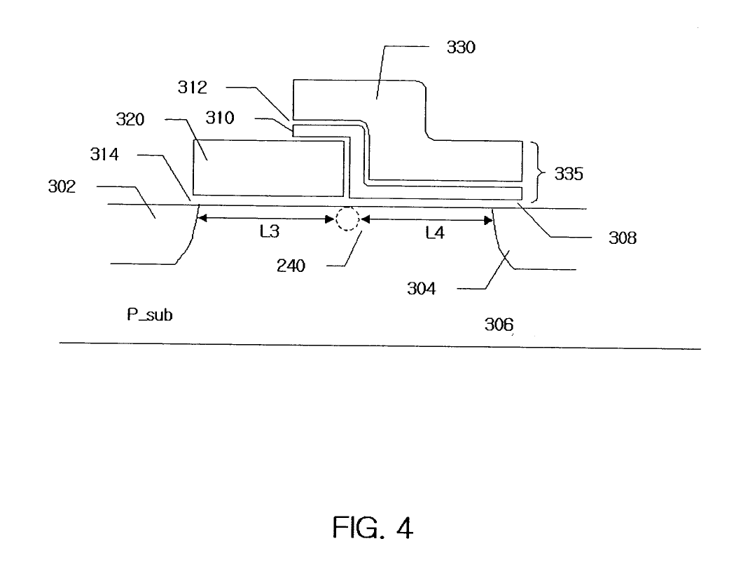

FIGS. 3 and 4 show cross sections of two different embodiments of each of memory cells 102 and 104. Non-volatile memory cells 102, 104 are described in copending application Ser. No. 10/394,17, entitled “NON-VOLATILE MEMORY DEVICE”, the content of which is incorporated herein by reference in its entirety.

Writing the Latch or the SRAM Circuit

To store a 1 in the latch circuit or the SRAM cell, voltage supply Vcc is applied to bitline BL and to wordline WL, while supply voltage Vss is applied to bitline \overline{BL}. In some embodiments of the present invention, supply voltage Vcc is between 1.2 to 5.5 volts and supply voltage Vss is at the ground potential (i.e., 0 volts). Terminals Cg, Cc and A are also held at the Vss potential. Because transistor 106 is in a conducting state, node C is raised to voltage Vcc-Vt, where Vt is the threshold voltage of any of the MOS transistors 106 and 108. Similarly, because transistor 108 is in a conducting state, node D is pulled to Vss volts (i.e., the voltage present on bitline \overline{BL}). Therefore, node C is charged to (Vcc-Vt) volts and node D is charged to 0 volts, thereby storing a 1 in the latch circuit. In the embodiments employing a latch circuit, to ensure that nodes C and D maintain their respective voltages of Vcc-Vt and 0 volts, after a 1 is stored in the latch circuit during a programming cycle, transistors 106 and 108 may be turned on periodically during refresh cycles

To store a 0 in the latch circuit or the SRAM cell, voltage supply Vcc is applied to bitline \overline{BL} and to wordline WL, while supply voltage Vss is applied to bitline BL. Terminal Cg is also held at the Vss potential. Because transistor 108 is in a conducting state, node D is raised to voltage Vcc-Vt. Similarly, because transistor 106 is in a conducting state, node C is pulled to Vss volts. Therefore, the capacitance associated with node D is charged to (Vcc-Vt) volts, and the capacitance associated with node C is charged to 0 volts, thereby storing a 0 in the latch circuit. Refresh operations may also be carried out during refresh cycles to maintain the stored data. In the embodiments employing a latch circuit, to ensure that nodes D and C maintain their respective voltages of Vcc-Vt and 0 volts after a 1 is stored in the latch circuit during a programming cycle, transistors 106 and 108 may be turned on periodically during refresh cycles.

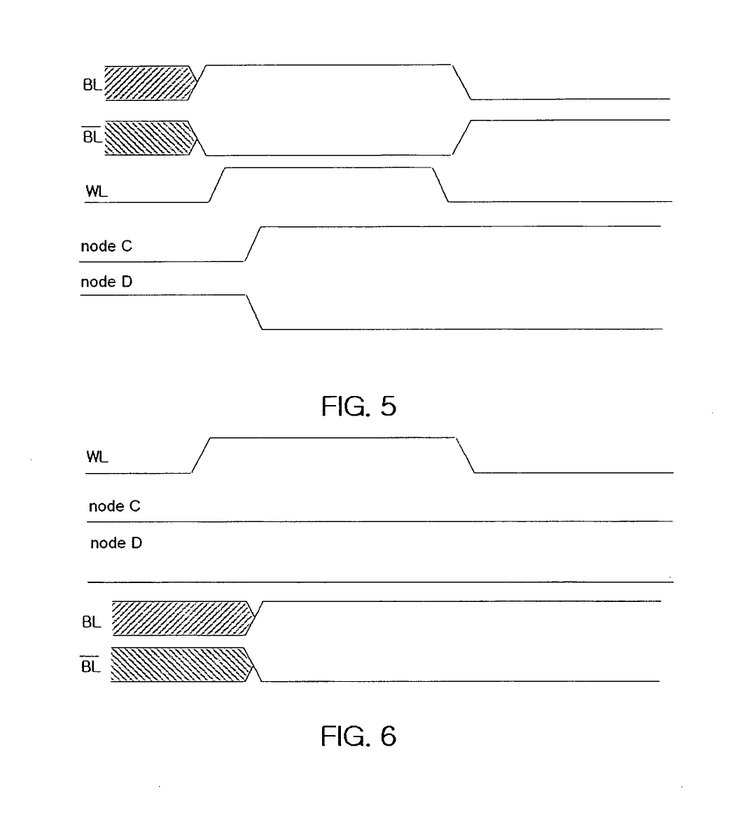

FIG. 5 is a simplified timing diagram of the voltages applied to bitlines BL, \overline{BL} as well as to wordline WL during a programming cycle of the latch circuit of memory structure 100. In accordance with FIG. 5 bitline BL and wordline WL are supplied with Vcc voltage while bitline \overline{BL} is supplied with Vss voltage. Accordingly, node C is charged to supply voltage (Vcc-Vt) and node D is pulled to the ground voltage. The voltages at nodes C and D are maintained at these values by periodically applying voltage Vcc to bitline BL and wordline WL, and applying voltage Vss to bitline \overline{BL}, as described above.

Reading the Latch or the SRAM Cell

To read the data stored in the latch circuit, supply voltage Vcc is applied to input terminal WL of memory 100, thereby coupling nodes C and D of memory 100 to bitlines BL and \overline{BL}, respectively. The voltages present on nodes C and D cause the bitline voltages to change in order to enable a read circuitry, such as a sense amplifier (not shown) to sense this voltage difference and generate a corresponding output signal, as is known by those skilled in the art. FIG. 6 is a simplified timing diagram of the voltage applied to input terminal WL of memory 100 during a read cycle of the latch circuit. In accordance with FIG. 6, input terminal WL is raised to supply voltage Vcc, thereby coupling nodes C and D to bit lines BL and \overline{BL}, respectively. Because nodes C and D respectively have high and low stored charges, bit lines BL and \overline{BL} are respectively raised to high and low voltages.

Erasing Non-Volatile Memory Cells

Referring to FIG. 2, non-volatile memory cells (hereinafter alternatively referred to as NVM) cells 102, 104 are erased before they are programmed. To erase the NVM cells 102, 104, terminals A, B of memory 100 are pulled to the Vss voltage. A relatively high negative voltage, e.g., −10 volts is applied to control gate terminal Cc. Guiding gate terminal Cg is either left floating or receives Vss or a small negative voltage. The application of these voltages causes electrons trapped in the nitride layer—formed between the respective control gate regions and the substrate regions of non-volatile devices 102, 104—to return to the substrate region and/or holes to be trapped in these nitride layers—due to hot hole injection—thereby neutralizing any trapped electrons. The tunneling of trapped electrons back to the substrate and/or trapping of holes in the respective nitride layers causes NVM cells 102, 104 to erase.

Programming Non-Volatile Memory Cells using Hot-Electron Injection

Non-volatile memory cells 102, 104 operate differentially in that if one of them, e.g., 102 is programmed to store a 1, the other one, e.g., 104 is programmed to store a 0. Therefore, during a read operation, if one of the non-volatile memory cells, e.g., 102 supplies a 1, the other one of the NVM cells, e.g., 104 supplies a 0.

In order to load data in non-volatile memory cells 102, 104, non-volatile memory cells 102, 104 are first erased, as described above. Assume that the data to be stored is a 1. Therefore voltage supply Vcc is applied to bitline BL and to wordline WL, while supply voltage Vss is applied to bitline \overline{BL}. To load this data in the non-volatile memory cells, 0 volt is applied to substrate terminal B of memory 100, a relatively high voltage Vpp in the range of, e.g., 5 to 12 volts is applied to terminal Cc of memory 100, a second voltage in the range of, e.g., 0.5 to 1.5 volts is applied to guiding gate terminal Cg, and a third voltage in the range of, e.g., 3 to 5 volts is applied to terminal A of memory structure 100.

Because the voltage at the guiding gate of non-volatile memory cell 102 is less than its source voltage, non-volatile memory cell 102 is not turned on. Accordingly, no current flows from the source to the drain of non-volatile memory cell 102 and thus no hot electron current is generated in the channel region of non-volatile memory cell 102. Therefore, non-volatile memory cell 102 is kept at the erased state and its threshold voltage is maintained at its erased value. Moreover, because there is a small difference between voltages at terminals A and Cg of non-volatile memory cell 102 and because the difference between the voltage applied to control gate terminal Cc and terminal A (i.e., the drain terminal of non-volatile memory cell 102) is relatively small, the voltage difference across the nitride layer of non-volatile memory cell 102 is insufficient to cause Fowler-Nordheim tunneling of electrons to occur in non-volatile memory cell 102. Accordingly, non-volatile memory cell 102 maintains its previous discharge state and thus its threshold voltage remains at its erased value.

Because the source region of non-volatile memory cell 104 (i.e., bitline \overline{BL}) is at 0 volt, and a voltage in the range of, e.g., 0.5 to 1.5 volts is applied to guiding gate terminal Cg, non-volatile memory cell 104 operates in a weak turn-on (e.g., subthreshold) state as a channel is formed under its guiding gate. Because, a third voltage in the range of, e.g., 3 to 5 volts is applied to the drain region (i.e., terminal A), a relatively small current flows between the source and drain terminals of non-volatile memory cell 104. The weak channel formed under the guiding gate of non-volatile memory cell 104 remains close to the ground potential. Because the voltage applied to the control gate Cc of non-volatile memory cell 104 is greater than its drain voltage, the voltage in the channel region formed under the control gate of non-volatile memory cell 104 is close to the device's drain voltage, thereby causing a relatively large lateral electric field to develop near the gap separating the channel regions formed between the guiding gate and control gate of non-volatile memory cell 104. The relatively high electric field causes electrons passing through the gap—as they drift from the source to the drain region—to gain the energy required to surmount the silicon-oxide barrier and thus to flow into and get trapped in the nitride layer. The electrons are trapped in the nitride layer under the control gate and are positioned relatively away from the drain region of non-volatile memory cell 104, thereby increasing the threshold voltage of non-volatile memory cell 104. The charges remain trapped in non-volatile memory cell 104 after power is turned off. Therefore, non-volatile memory cell 104 maintains its higher threshold even after power is turned off. The increase in the threshold voltage of non-volatile memory cell 104 is used to read the contents of the non-volatile memory cell, as described further below.

Therefore, non-volatile memory cell 104 is programmed (i.e., charged) whereas non-volatile memory cell 102 is not programmed (i.e., is not charged). Therefore, during each such cycle, one of the non-volatile memory cells of memory structure 100 is programmed and the other one of the non-volatile memory cells of memory structure 100 remains erased. It is understood, that if the capacitance associated with bitline BL had stored 0 volt and the capacitance associated with bitline \overline{BL} had stored Vcc volt, after the above programming cycle, non-volatile memory cell 102 would be programmed and non-volatile memory cell 104 would remain in an erased stated. The differential programming, whereby one of the non-volatile memory cells is programmed while the other one remains erased, provides advantages that are described further below.

Programming of Non-Volatile Memory Cells using Tunneling

Assume that a 1 is to be stored in memory structure 100. Therefore voltage supply Vcc is applied to bitline BL and to wordline WL, while supply voltage Vss is applied to bitline \overline{BL}. To store this data in non-volatile memory cells 102, 104, 0 volt is applied to substrate terminal B of memory structure 100. A voltage in the range of, e.g., 1.2 volts to Vcc is applied to node A to precharge this node. After this pre-charge, node A is left floating.

A voltage in the range of, e.g., 0.4 to 2 volts is applied to guiding gate terminal Cg of memory structure 100. Because the voltage at bitline BL is in the range of, e.g., Vcc volts, no channel is formed in the substrate under the guiding gate of transistor 102. Therefore, no current flows from node A to bitline BL via non-volatile memory cell 102. Because bitline \overline{BL} is at, e.g., 0 volt, a channel is formed in the substrate under the guiding gate of non-volatile memory cell 104.

A relatively high programming voltage Vpp, in the range of, e.g., 4 to 8 volts is applied to control terminal Cc of memory structure 100. Due to the capacitive coupling, the applied Vpp voltage causes a channel to be formed under the control gate of non-volatile memory cells 102, 104. Therefore, a current is enabled to flow from bitline \overline{BL} to node A via non-volatile memory cell 104. As is understood by persons skilled in the art, applied voltages, such as Vpp are pulse voltages. Accordingly, the voltage that is coupled to form a channel under the control gate of non-volatile memory cell 102 decays as a function of time. The characteristic time constant of this decay is determined by an RC time-constant, where R is the combined resistance associated with non-volatile memory cells 102 and 104, and C is the capacitance associated with the nitride layer and bitline \overline{BL}. Resistance R may be varied by the voltage applied to guiding gate terminal Cg and increases when the voltage applied to guiding gate terminal Cg cause a channel to form under the guiding gates of non-volatile memory cell 104.

When the Vpp voltage pulse is applied, a current discharges via non-volatile memory cell 104 to bitline \overline{BL}. If the RC time constant, described above, is substantially similar to the Vpp pulse duration, a voltage gradient is formed in the channel region of each of non-volatile memory cells 102 and 104. Because no channel is formed under the guiding gate of non-volatile memory cell 102, a relatively high voltage exists near the gap between the control and guiding gates of non-volatile memory cell 102. Because a channel is formed under the guiding gate of non-volatile memory cell 104, a relatively low voltage exists near the gap between the control and guiding gates of non-volatile memory cell 104.

Because of the relatively large difference between the applied Vpp voltage and the voltage which exists near the gap separating the control and guiding gates of non-volatile device memory cell 104, a relatively large number of electrons tunnel through the respective oxide layer and are trapped in the nitride layer of non-volatile device memory cell 104. Because of the relatively small difference between the applied Vpp voltage and the voltage which exists near the gap separating the control and guiding gates of non-volatile memory cell 102, a relatively small number of electrons tunnel through the respective oxide layer and are trapped in the nitride layer of non-volatile memory cell 102. In other words, more electrons are trapped in the nitride layer of non-volatile memory cell 104 than are trapped in the nitride layer of non-volatile device memory cell 102.

The difference in the number of trapped electrons, causes non-volatile memory cells 102 and 104 to have different threshold voltages. Because a relatively higher number of electrons are trapped in the nitride layer of non-volatile memory cell 104 than they are in the nitride layer of non-volatile memory cell 102, non-volatile memory cell 104 has a higher threshold voltage than does non-volatile memory cell 102. Consequently, non-volatile memory cell 104 is programmed to have a higher threshold voltage than is non-volatile memory cell 102, whose threshold voltage remains substantially the same as it is prior to the programming cycle. As is seen from the above, during each such programming cycle, one of the non-volatile devices is programmed to have a higher threshold than the other. The differential programming provides advantages that are described further below. The charges remain trapped in non-volatile memory cell 104 after power is turned off. Therefore, non-volatile memory cell 104 maintains its higher threshold even after power is turned off. The relatively higher threshold voltage of non-volatile memory cell 104 compared to that of non-volatile memory cell 102 is used to read the contents stored therein.

The trapped electrons are spatially positioned in the nitride layer above the channel region. The largest concentration of electrons trapped in non-volatile memory cell 104 is spaced near the guiding gate edge and at a distance that is relatively away from the drain region of non-volatile memory cell 104. In contrast, for non-volatile memory cell 102, the smallest concentration of trapped electrons is spaced near the guiding gate edge and at a distance that is relatively away from its drain region. As is known by those skilled in the art, the trappings of the electrons near the source region raises the threshold voltage of the device.

Reading the Non-Volatile Memory Cells

To initiate a read of the non-volatile memory cells, both BL and \overline{BL} lines are pulled down to the ground potential. The Vcc voltage is applied to terminals A and Cg of memory structure 100. A relatively small sensing voltage (i.e. less than the Vcc voltage) is applied to terminal Cc. The sensing voltage is selected so as to be larger than the threshold voltage of the erased non-volatile memory cell and smaller than the threshold of the programmed non-volatile memory cell.

Because the gate-to-source voltage of non-volatile memory cell 102 is greater than its threshold voltage and because of the presence of a voltage across the drain and source terminals of non-volatile memory cell 102, a current flows between drain and source terminals of non-volatile memory cell 102. Depending on the magnitude of the increase in the threshold voltage of non-volatile memory cell 104, either non-volatile memory cell 104 conducts no current or, alternatively conducts a current with a magnitude that is smaller than that conducted by non-volatile memory cell 102.

The difference between the magnitude of the currents flowing through non-volatile memory cell 102 and that, if any, flowing through non-volatile memory cell 104, results in differential charging of bitline BL and bitline \overline{BL}. Because bitline BL is charged at a higher rate than bitline \overline{BL}, bitline BL is charged to a higher potential than bitline \overline{BL}. Therefore, the voltage at bitline BL is restored to its prior voltage value representative of logic state 1 while the voltage at bitline \overline{BL} is restored to its prior voltage value representative of logic state of 0.

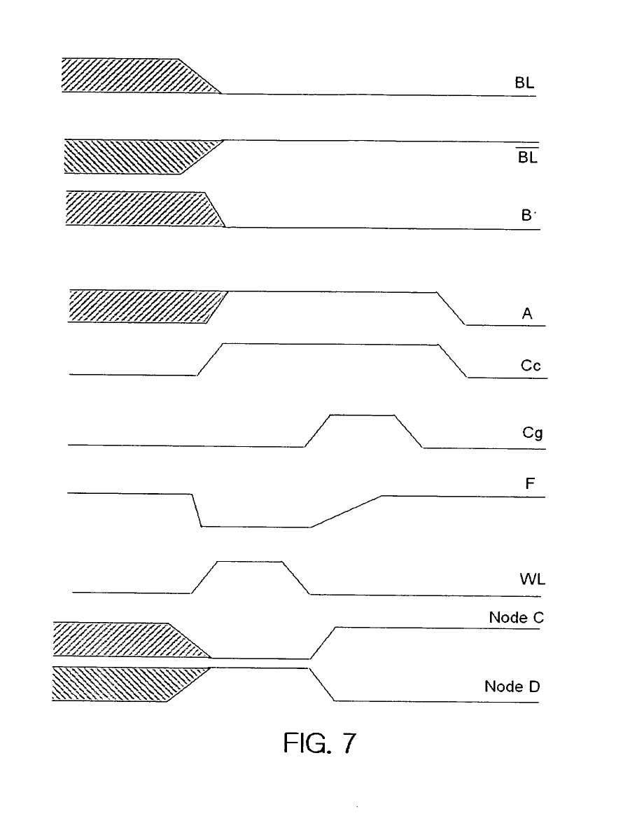

FIG. 7 shows the voltages applied to various terminals of memory structure 100 during a non-volatile memory cell recall (readout) operation. As is seen from FIG. 7, input terminal Cg is raised to the supply voltage Vcc, thus enabling bitlines BL and \overline{BL} to receive the voltages from memory cells 102 and 104, respectively. Application of a relatively low read voltage (sensing voltage) to terminal Cc causes bitline BL and bitline \overline{BL} to respectively restore their relatively high and low voltages.

As described above, when data stored in non-volatile memory cells 102 and 104 are read out, the current flow through non-volatile memory cells 102 and 104 is differential. Therefore, any change in the threshold voltages of non-volatile memory cells 102 and 104 due to over-erase also occurs differentially. The differential current flow through non-volatile memory cells 102 and 104, in accordance with the present invention, minimizes any data retention or read errors that may occur as a result of over erasing non-volatile devices 102 and 104 during erase cycles.

Data Transfer from the Non-Volatile Memory Cell to SRAM Cell

Referring to FIG. 2, data may also be written directly from non-volatile memory cells 103 to SRAM cell 105. To achieve this, first, both BL and \overline{BL} lines are pulled down to the ground potential and nodes C and D are discharged to the ground potential. The discharge of nodes C and D is performed by applying Vcc voltage to terminal WL so as to enable these nodes to discharge to ground via bit lines BL and \overline{BL}. Terminal F may be coupled to ground or may float. After discharging bit lines BL, \overline{BL}, the Vcc voltage is applied to terminals A and Cg of memory structure 100. A relatively small sensing voltage (i.e. less than the Vcc voltage) is applied to terminal Cc. The sensing voltage is so selected as to be larger than the threshold voltage of the erased non-volatile memory cell and smaller than the threshold of the programmed non-volatile memory cell.

Assume that the non-volatile memory cell 104 has been programmed. Because the gate-to-source voltage of non-volatile memory cell 102 is greater than its threshold voltage and because of the presence of a voltage across the drain and source terminals of non-volatile memory cell 102, a current flows between drain and source terminals of non-volatile memory cell 102. Depending on the magnitude of the increase in the threshold voltage of non-volatile memory cell 104, either non-volatile memory cell 104 conducts no current or, alternatively conducts a current with a magnitude that is smaller than that conducted by non-volatile memory cell 102.

The difference between the magnitude of the currents flowing through non-volatile memory cell 102 and that, if any, flowing through non-volatile memory cell 104, results in differential charging of bitline BL and bitline \overline{BL}. Because bitline BL is charged at a higher rate than bitline \overline{BL}, bitline BL is charged to a higher potential than bitline \overline{BL}. Therefore, the voltage at bitline BL is restored to its prior voltage value representative of logic state 1 while the voltage at bitline \overline{BL} is restored to its prior voltage value representative of logic state of 0. After restoring bitlines BL and \overline{BL}, if terminal F is at the ground potential, it is enabled to float afterwards. The voltages of bitlines BL and \overline{BL} are received by nodes C and D as differential charging of bitlines BL and \overline{BL} occurs. Thereafter, the Vcc voltage is gradually applied to terminal F, to enable nodes C and D to reach their final voltage values.

Data Transfer from SRAM Cell to the Non-Volatile Memory Cell

Data may be written directly from the SRAM cell to the non-volatile memory cells. To achieve this, first, a recall operation of the SRAM cell is performed, as described above. The result of this operation leads to the differential charging of bitlines BL and \overline{BL}. For example, if the SRAM cell is assumed to store high and low charges at nodes C and D, then bitlines BL and \overline{BL} are respectively raised to high and low voltages. Subsequently, non-volatile memory cells 102, 104 are programmed using hot-electron injection or tunneling, in the same manner as described above. Thus, for example, if the bitlines BL and \overline{BL} were respectively at Vcc and 0 Volts, then non-volatile memory cell 102 is programmed and non-volatile memory cell 104 remains in the erased state.

Programming Multiple Devices Along the Same Wordline

In accordance with some embodiments, integrated memory structure 100 is positioned in an array of integrated memory cell structures. Within such a memory array, each terminal of each integrated memory structure is provided with a voltage, according to the operation of the memory structure in the array. In particular, the first terminal of a number of integrated memory structures may be coupled to the same wordline. Thus, if a Vcc voltage is applied to that wordline, nodes C and D of each such integrated memory becomes coupled to their respective bitlines BL and \overline{BL}. Accordingly if, for example, proper programming voltages are applied, the SRAMs disposed in all the integrated memory structures coupled to that wordline are programmed concurrently. In accordance with another example, if proper programming voltages are applied, the non-volatile memory cells disposed in all the integrated memory structures coupled to that wordline are programmed concurrently.

Integrated Memory Structure with Multiple SRAM and/or Multiple Non-Volatile Memory Cells

FIG. 9 is a block diagram of an integrated memory structure 500, in accordance with one embodiment of the present invention, that is shown as including m non-volatile memory cells 103 (FIG. 2), namely 103₁ . . . 103ₘ (FIG. 2) and n SRAM cells 105 (FIG. 2), namely 105₁ . . . 105₂, where m may be different than n. Each integrated memory structure 500 may be part of a memory array disposed in a semiconductor Integrated Circuit adapted, among other functions, to store and supply stored data.

As is seen concurrently from FIGS. 2 and 9, each non-volatile memory cell 103 of integrated memory structure 500, includes two non-volatile devices 102, 104, that are coupled to true and complementary bitlines BL and \overline{BL} associated therewith. Each non-volatile memory cell 103 includes a pair of terminals Cc and Cg. Accordingly, non-volatile memory cell 103₁ includes terminals Cc₁ and Cg₁; similarly non-volatile memory cell 103ₘ includes terminals Ccₘ and Cgₘ.

Furthermore, as seen concurrently from FIGS. 2 and 9, each SRAM cell 105 of integrated memory structure 500 is also coupled to true and complementary bitlines BL and \overline{BL}, and to a wordline associated with that SRAM. For example, SRAM 105₁ is coupled to wordline WL₁; similarly SRAM 105ₙ is coupled to wordline WLₙ. Accordingly, as seen from FIG. 9, each integrated memory structure 500 is coupled to a pair of true and complementary bitlines BL and \overline{BL} as well as to n wordlines.

Memory Cells Arranged in an Array

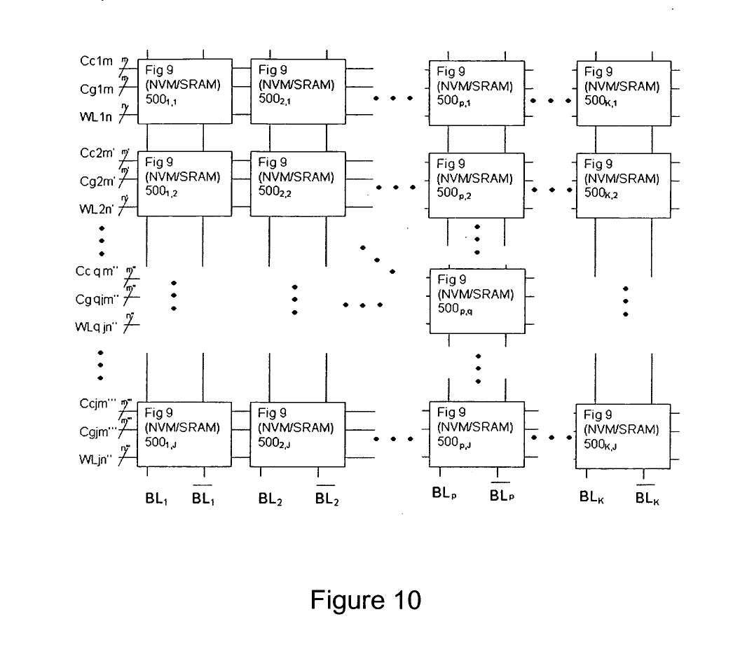

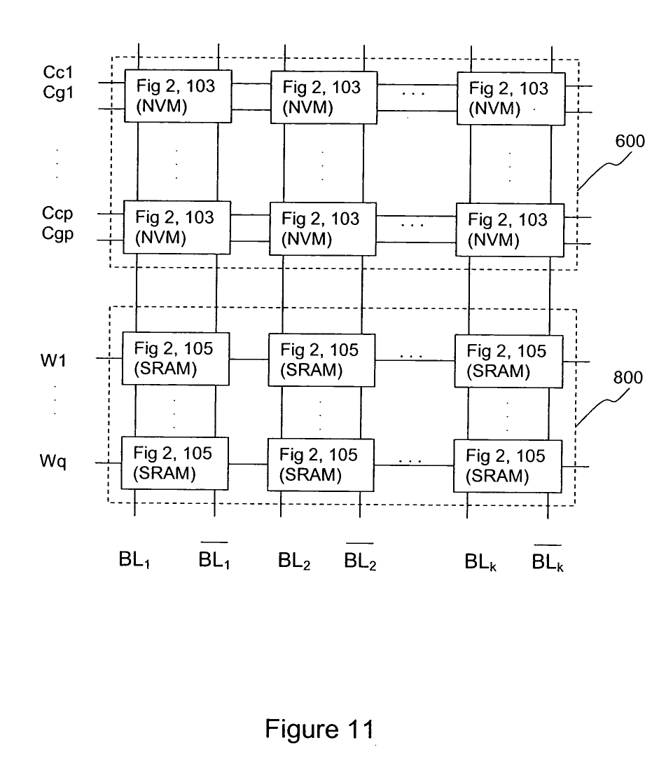

Each integrated memory structure of the present invention, such as those shown in FIGS. 2 and 9, may be disposed in an array. FIG. 10 shows a J×K array 700 of integrated memory structures 500. Each integrated memory structure 500 is alternatively referred to herein below by reference numeral 500_{J,K} where index J identifies the row and index K identifies the column in which that integrated memory structure 500 is disposed in. For example, the integrated memory structure 500 disposed in column 2, row 3 is identified with reference numeral 500_{2,3}; similarly the integrated memory structures disposed in column p, row q is identified with reference numeral 500_{p,q}.

The integrated memory structures 500 disposed along the same row of memory array 700 share the same set of control gate terminal Cc, the same set of guiding gate terminal Cg, and the same set of wordline terminals WL. The number of terminals in the same set of Cc terminals, the same set of Cg terminals, and the same set of WL terminals, are determined by the number of non-volatile memory cells as well as the number of SRAM cells disposed in each integrated memory structure 500. Furthermore, the integrated memory structures disposed along the same column of array 700 receive the same true and complementary bit lines. For example, the integrated memory structures disposed along column 1 of array 700, receive true and complementary bit lines BL1, \overline{BL}₁; similarly the integrated memory structures disposed along column k of array 700, receive true and complementary bit lines BLₖ, \overline{BL}ₖ.

An integrated memory structure 500 disposed in a column of array 700 may include a different number of non-volatile memory cells and SRAMs than another integrated memory structure disposed in the same column. For example, integrated memory structure 500_{2,3} may include a different number of non-volatile memory cells and/or SRAMs than does, for example, integrated memory structure 500_{4,3}. An integrated memory structure disposed in a row of array 700 however includes the same number of non-volatile memory cells as do other integrated memory structures disposed in the same row. Likewise, an integrated memory structure disposed in a row of array 700 includes the same number of SRAMs as do other integrated memory structures disposed in the same row. Exemplary array 700 illustrates how the SRAM cells and the non-volatile cells may be arranged in a variety of array configurations, according to the number of non-volatile structures and SRAM cells within each row of the array.

Data Transfer Among Multiple SRAM Cells and or Multiple NVM Cells

In accordance with some embodiments of present invention, such as those shown in FIGS. 2, 9, and 10, data transfer between the SRAMs and non-volatile memory cells coupled to the same true and complementary bit lines may be performed in a number of ways. Transferring of data between a particular SRAM cell and a particular NVM cell, may be carried out as described above and using terminals CC, Cg, and WL corresponding to the cells between which the transfer is to take place.

Layout Flexibility

FIG. 11 shows an L×M array 900 of integrated memory structures, in accordance with another embodiment of the present invention. Referring concurrently to FIGS. 2 and 11, array 900 is configured to include P×K rows of NVM cells 103 and Q×K rows of SRAMs 105. Therefore, there are Q SRAMs 105 associated with P NVM cells 103.

As shown in FIG. 11, NVM cells 103 (FIG. 2) are physically placed adjacent to one another to form a first array 600, and SRAM cells 105 are also physically placed adjacent to one another to form a second array 800. Thus, in the layout floor plan of the fabricated array, the non-volatile memory cells form a first array and the SRAM cells form a second array. The Non-volatile and SRAM memory arrays are distinct arrays that share common bit lines, as shown in FIG. 11. In this manner, flexibility is provided both in design and floor planning of the array.

The above embodiments of the present invention are illustrative and not limitative. The invention is not limited by the type of non-volatile memory transistor disposed in the memory cell of the present invention. Moreover, both N-channel and P-channel transistors may be used to form the SRAM as well as the non-volatile memory cells of the present invention. The invention is not limited by the type of integrated circuit in which the memory cell of the present invention is disposed. For example, the memory cell, in accordance with the present invention, may be disposed in a programmable logic device, a central processing unit, and a memory having arrays of memory cells or any other IC which is adapted to store data.

While the invention is described in conjunction with the preferred embodiments, this description is not intended in any way as a limitation to the scope of the invention. Modifications, changes, and variations, which are apparent to those skilled in the art, can be made in the arrangement, operation and details of construction of the invention disclosed herein without departing from the spirit and scope of the invention.

1. A memory structure comprising:
a first MOS transistor having a first current carrying terminal directly coupled to a first node, a second current carrying terminal directly coupled to a first bitline associated with the memory structure, and a gate terminal directly coupled to a first terminal of the memory structure;
a second MOS transistor having a first current carrying terminal directly coupled to the first node, a gate terminal directly coupled to a second node, and a second current carrying terminal adapted to receive a first voltage;
a first non-volatile memory cell comprising:
a first substrate region directly coupled to a second terminal of the memory structure;
a source region formed in the first substrate region and directly coupled to the first bitline;
a drain region formed in the first substrate region and separated from the source region by a first channel region; said drain region being directly coupled to a third terminal of the memory structure;
a first gate overlaying a first portion of the first channel region and separated therefrom via a first insulating layer; said first gate directly coupled to a fourth terminal of the memory structure; and
a second gate overlaying a second portion of the first channel region and separated therefrom via a second insulating layer; wherein said first portion of the first channel region and said second portion of the first channel region do not overlap and wherein said second gate is directly coupled to a fifth terminal of the memory structure; said first non-volatile memory cell being adapted so as not to include a floating gate disposed between said first and second gates thereof;
a third MOS transistor having a first current carrying terminal directly coupled to the second node, a second current carrying terminal directly coupled to a second bitline associated with the memory structures, and a gate terminal directly coupled to the first terminal of the memory structure;
a fourth MOS transistor having a first current carrying terminal directly coupled to the second node, a gate terminal directly coupled to the first node, and a second current carrying terminal adapted to receive the first voltage; and
a second non-volatile memory cell comprising:
a second substrate region directly coupled to the second terminal of the memory structure;
a source region formed in the second substrate region and directly coupled to the second bitline associated with the memory structure;
a drain region formed in the second substrate region and separated from the source region of the second substrate region by a second channel region; said drain region of the second substrate region being directly coupled to the third terminal of the memory structure;
a first gate overlaying a first portion of the second channel region and separated therefrom via a first insulating layer and directly coupled to the fourth terminal of the memory structure; and
a second gate overlaying a second portion of the second channel region and separated therefrom via a second insulating layer, wherein said first portion of the second channel region and said second portion of the second channel region do not overlap and wherein said second gate overlaying the second portion of the second channel region is directly coupled to the fifth terminal of the memory structure, said second non-volatile memory cell being adapted so as not to include a floating gate disposed between said first and second gates thereof.

2. The memory structure of claim 1 wherein the first and second nodes receive their respective voltages from the first and second bitlines and maintain their respective voltages after the fist and second MOS transistors are turned off.

3. The memory structure of claim 2 wherein the second terminal of the memory structure is adapted to receive the first voltage, the third terminal of the memory structure is adapted to receive a second voltage, the fourth terminal of the memory structure is adapted to receive a third supply voltage, and the fifth terminal of the memory structure is adapted to receive a fourth supply voltage.

4. The memory structure of claim 3 wherein the fourth voltage is greater than the first, second, and third voltages.

5. The memory structure of claim 4 wherein the first voltage is 0 volt.

6. The memory structure of claim 4 wherein during a write cycle one of the first and second non-volatile memory cells traps more electrons in its nitride layer than does the other one of the first and second non-volatile memory cells.

7. The memory structure of claim 6 wherein the electrons are trapped via hot-electron injection.

8. The memory structure of claim 6 wherein the electrons are trapped via tunneling.

9. The memory structure of claim 8 wherein after the write cycle, the first voltage is applied to the first and second terminals, the second voltage is applied to the third and fifth input terminals, and a fifth voltage is applied to the fourth terminal, wherein the fifth voltage is smaller than the second voltage.

10. The memory structure of claim 9 wherein the trapped electrons are untrapped by applying the first voltage to first second and third terminals of the memory structure, applying a negative voltage to the fifth terminal of the memory structure and by enabling the fourth terminal of the memory structure to float.

11. The memory structure of claim 10 wherein said first and second non-volatile memory cells are operated in subthreshold regions.

12. The memory structure of claim 3 wherein the fist terminal of the memory structure is adapted to receive the second voltage.

13. The memory structure of claim 12 wherein the first and second nodes receive voltages from the first and second non-volatile memory cells respectively via the first and second bitlines.

14. The memory structure of claim 1 wherein said memory structure is disposed in a memory array.

15. The memory structure of claim 13 wherein said memory structure is a redundant memory structure disposed in a memory array and for repair use.

16. The memory structure of claim 1 wherein said first and second MOS transistors are periodically turned on.

17. The memory structure of claim 1 wherein said memory cell includes at least one resistive load.

18. The memory structure of claim 1 wherein said memory structure includes more than one pair of non-volatile memory cells and or more than one SRAM cell attached to the same bitline.

19. The memory structure of claim 13 wherein voltages applied to the said memory structure are applied at the same time the same voltages are applied to another memory structure within the memory array.

20. The memory structure of claim 14 wherein the non-volatile memory cells are adjacent to non-volatile memory cells of the other memory structures in the memory array.
